(19) United States
(12) Patent Application Publication
(10) Pub. No.: US 2022/0415839 A1
(43) Pub. Date: Dec. 29, 2022

(54) UNIVERSAL HYBRID BONDING SURFACE LAYER USING AN ADAPTABLE INTERCONNECT LAYER FOR INTERFACE DISAGGREGATION

(71) Applicant: Intel Corporation, Santa Clara, CA (US)

(72) Inventors: Aleksandar ALEKSOV, Chandler, AZ (US); Feras EID, Chandler, AZ (US); Johanna M. SWAN, Scottsdale, AZ (US); Adel A. ELSHERBINI, Chandler, AZ (US); Shawna M. LIFF, Scottsdale, AZ (US)

(21) Appl. No.: 17/357,722

(22) Filed: Jun. 24, 2021

(51) Int. Cl. H01L 23/00; H01L 25/065

(52) U.S. Cl. CPC H01L 24/25; H01L 24/05; H01L 24/06; H01L 24/08; H01L 25/0652; H01L 2224/06051; H01L 2224/05014; H01L 2224/06132; H01L 2224/2512

(57) ABSTRACT

Embodiments disclosed herein include semiconductor dies with hybrid bonding layers and multi-die modules that are coupled together by hybrid bonding layers. In an embodiment, a semiconductor die comprises a die substrate, a pad layer over the die substrate, where the pad layer comprises first pads with a first dimension and a first pitch and second pads with a second dimension and a second pitch. In an embodiment, the semiconductor die further comprises a hybrid bonding layer over the pad layer. In an embodiment, the hybrid bonding layer comprises a dielectric layer, and an array of hybrid bonding pads in the dielectric layer, wherein the hybrid bonding pads comprise a third dimension and a third pitch.

### TECHNICAL FIELD

Embodiments of the present disclosure relate to electronic packages, and more particularly to electronic package architectures with a universal hybrid bonding surface layer.

### BACKGROUND

Complex computational systems are increasingly based on the principle of heterogeneous integration, where many semiconductor devices/chips using diverse technologies (and materials) are synthesized into one functional unit that satisfies diverse computational needs of the future. Hybrid bonding is a key technology that will enable continuous computational and bandwidth scaling of such systems. Heterogeneously integrated computational systems where vertical connections between different computational strata are enabled by hybrid bonding consist of many individual semiconductor tiles/chiplets/dies.

A critical process operation for the manufacturing of such hybrid bonded systems is the creation of the hybrid bonding interface. Precise chemical mechanical polishing (CMP) is required to obtain the structures and dimensions necessary for a high yield hybrid bonding process. However, CMP is very dependent on metal density and feature sizes. For existing hybrid bonding interfaces, this would mean that for every platform (or even every product skew) the CMP process needs to be tuned to enable optimal hybrid bonding capability. This is because the layout and dimensions of the pad layer may be different and the metal density and dielectric design rules will vary. The result is that a significant number of CMP processing variations are needed for each product even if nominally on the same process node or sub-node.

### BRIEF DESCRIPTION OF THE DRAWINGS

FIG. 1A is a plan view illustration of a hybrid bonding interface layer using existing architectures.

FIG. 1B is a plan view illustration of a hybrid bonding interface with a uniform array of hybrid bonding pads, in accordance with an embodiment.

FIG. 2 is an illustration of various layers to provide a uniform hybrid bonding interface, in accordance with an embodiment.

FIG. 3A is a cross-sectional illustration of a base die that is coupled to a plurality of chiplets using a uniform hybrid bonding interface, in accordance with an embodiment.

FIG. 3B is a cross-sectional illustration of a base die with a hybrid bonding interface that is bonded to chiplets that have standard bonding interfaces, in accordance with an embodiment.

FIG. 4A is a plan view illustration of a single pad that is connected to a plurality of hybrid bonding pads, in accordance with an embodiment.

FIG. 4B is a plan view illustration of a plurality of pads that are connected to a single hybrid bonding pad, in accordance with an embodiment.

FIG. 5A is a cross-sectional illustration of a multi-die module with a plurality of strata that are coupled together by hybrid bonding interfaces, in accordance with an embodiment.

FIG. 5B is a plan view illustration of a portion of the interface between a first strata and a second strata of the multi-die module, in accordance with an embodiment.

FIG. 5C is a plan view illustration of a portion of the interface between the second strata and a third strata of the multi-die module, in accordance with an embodiment.

FIG. 5D is a cross-sectional illustration of a portion of the multi-die module illustrating a hybrid bonding interface, in accordance with an embodiment.

FIG. 6A is a cross-sectional illustration of dies that are to be bonded together with hybrid bonding, where the alignment is perfect, in accordance with an embodiment.

FIG. 6B is a cross-sectional illustration of dies that are to be bonded together with hybrid bonding, where the alignment is off and adaptive lithography is used to correct the alignment, in accordance with an embodiment.

FIGS. 7A-7C are cross-sectional illustrations depicting a process to form a die with a uniform hybrid bonding interface, in accordance with an embodiment.

FIGS. 8A-8H are cross-sectional illustrations depicting a process to use adaptive lithography to correct alignment issues of hybrid bonding interfaces in a multi-die module, in accordance with an embodiment.

FIG. 9 is a cross-sectional illustration of an electronic system with a multi-die module assembled using uniform hybrid bonding interfaces, in accordance with an embodiment.

FIG. 10 is a schematic of a computing device built in accordance with an embodiment.

### EMBODIMENTS OF THE PRESENT DISCLOSURE

Described herein are electronic package architectures with a universal hybrid bonding surface layer, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

To provide context to embodiments disclosed herein, hybrid bonding is a process for bonding together semiconductor dies (which may be referred to as dies, chiplets, tiles, etc.) without the use of a solder. In a hybrid bonding (HB) process, an HB layer is provided on both dies. The HB layer comprises a dielectric layer with HB pads embedded in the dielectric layer. The top surfaces of the HB pads may be substantially coplanar with the top surface of the dielectric layer. In some instances, the top surface of the HB pads may be one to several nanometers below the top surface of the dielectric layer. To initiate the bonding, the pair of HB layers are brought into contact with each other. At substantially room temperature, the dielectric layers begin to bond to each other. The temperature may then be increased. This leads to the metal pads (typically Cu pads) that may have been slightly recessed, as mentioned, to touch since the coefficient of thermal expansion of the metal (e.g. Cu) is higher than that of the surrounding dielectric. This contact and the added temperature then causes interdiffusion between the HB pads on opposite dies. In some embodiments, the interdiffusion may even result in there being no discernable interface between the HB pads. That is, the HB pads may substantially merge to form a single conductive structure.

HB processes are particularly beneficial in multi-die modules because they can allow for extremely high-density interconnects. In some embodiments, pitches of the HB pads may be approximately 40 μm or smaller, or approximately 10 μm or smaller. As such, extremely high input/output (I/O) densities can be provided to increase bandwidth capabilities.

As noted above, HB architectures are limited by the need to have precise chemical mechanical polishing (CMP) processes that are heavily dependent on metal density and metal dimensions. As such, any alteration in the HB layer may require a new CMP recipe. Additionally, it is particularly difficult to design adequate CMP recipes when the HB layer has significant variations in the dimensions of the HB pads.

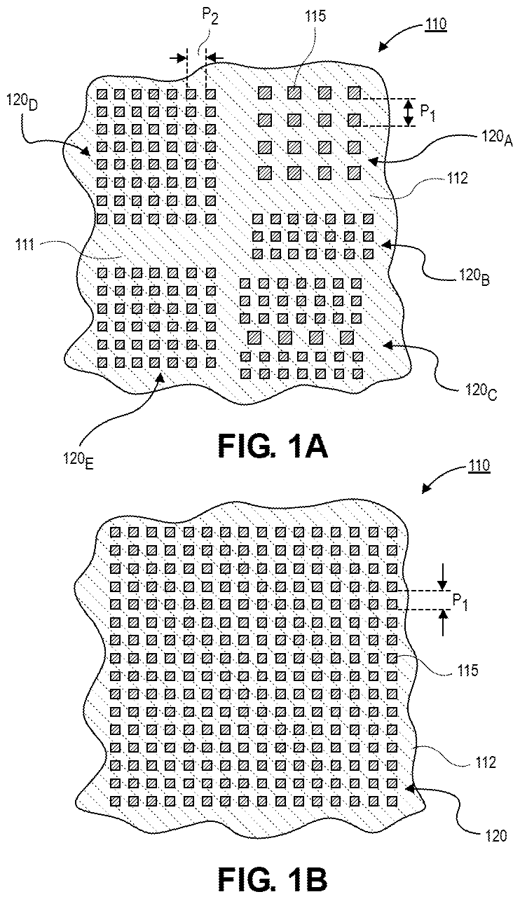

An example of an HB layer 110 is shown in FIG. 1A. As shown, the HB layer 110 comprises a plurality of pads 115 embedded in a dielectric layer 112. The pads 115 may comprise different dimensions. Additionally, different arrays 120_{A}-120_{E} have different pitches (e.g., a first pitch P₁ in array 120_{A} or a second pitch P₂ in array 120_{D}). Additionally, there are significant gaps 111 with no pads 115 between the different arrays 120. As such, the metal density is non-uniform. The variation in the arrays 120 is driven by the different dies that are to be coupled to an underlying die to form a multi-die module. The different dies may supply different functionalities, be at different process nodes, be from different suppliers, or have many other differences. As such, it is not currently possible to provide a uniform HB layer.

Accordingly, embodiments disclosed herein include architectures that enable the use of a uniform (or universal) HB layer. A uniform HB layer has the advantage of not needing different CMP recipes for different products since the HB layer will always be the same. Furthermore, a uniform HB layer provides a uniform metal density across the HB layer, which simplifies the CMP recipe. An example of a uniform HB layer is shown in FIG. 1B.

Referring now to FIG. 1B, a plan view illustration of a uniform HB layer 110 is shown, in accordance with an embodiment. As shown, the plurality of HB pads 115 are provided in a single array 120. The HB pads 115 have a uniform first pitch P₁ across the dielectric layer 112. It is to be appreciated that, due to the reasons described above, existing dies may not be directly compatible with such a uniform HB layer 110. Accordingly, embodiments disclosed herein include the use of a redistribution layer to re-route the pads on the die to be compatible with the uniform HB layer 110.

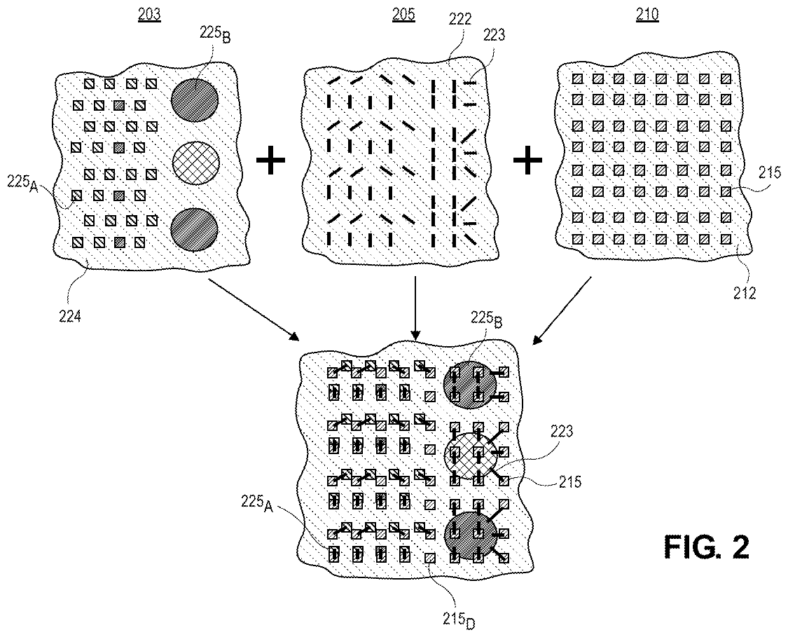

Referring now to FIG. 2, a series of layers 203, 205, and 210 are shown by themselves (top) and stacked together (bottom). In an embodiment, layer 203 is the existing pad layout of an die in a dielectric layer 224. The pads 225 may have non-uniform pitches and/or dimensions. For example, pads 225_{A} may be smaller and have a smaller pitch than pads 225_{B}. In some instances, pads 225_{A} may be I/O pads and pads 225_{B} may be power and/or ground pads.

Referring now to layer 205, redistribution traces 223 in a dielectric layer 222 are shown. The redistribution traces 223 re-rout the position of the underlying pads 225 to match the layout of the overlying HB pads 215 in the HB layer 210. The HB pads 215 may be in a dielectric layer 212.

As shown in the bottom composite illustration, each of the pads 225_{A} are routed to an HB pad 215. It is to be appreciated that vertical vias connecting the layers together are omitted for clarity. In some embodiments, the pads 225_{A} and the HB pads 215 may have a 1:1 ratio. In contrast the pads 225_{B} may have a one to many ratio. For example, in FIG. 2, the pads 225_{B} have a 1:6 or 1:9 ratio, though other ratios may also be provided. Also illustrated in FIG. 2 is the presence of dummy HB pads 215. The dummy HB pads 215_{D} may not be connected to any circuitry of the die. However, the presence of dummy HB pads 215_{D} keeps the metal density uniform, and therefore, enables a reduction in the complexity of the CMP recipe.

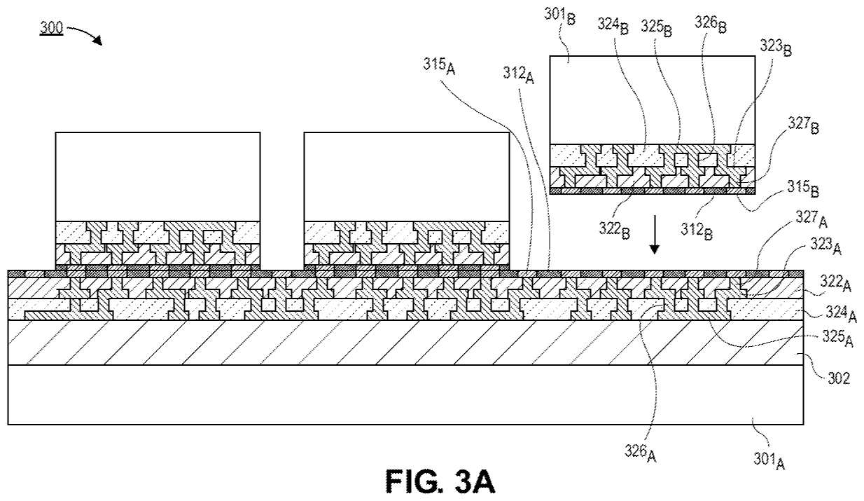

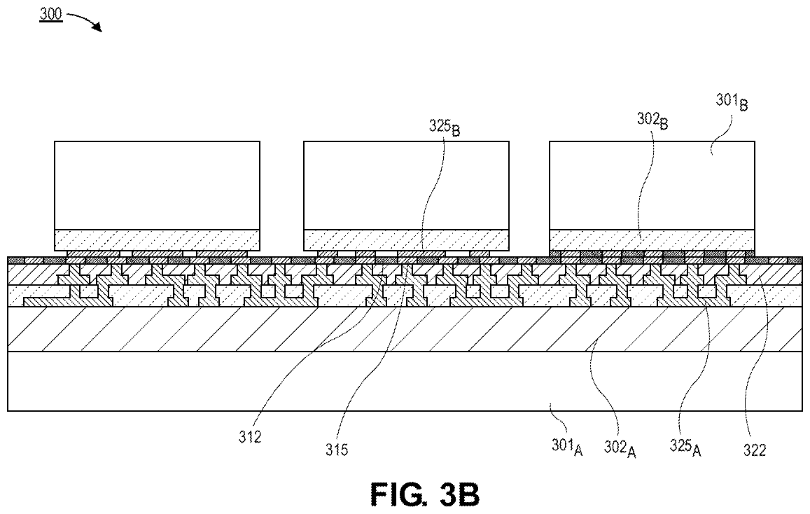

Referring now to FIG. 3A, a cross-sectional illustration of a multi-die module 300 is shown, in accordance with an embodiment. In an embodiment, the multi-die module 300 may comprise a base die 301_{A}. A plurality of chiplets 301_{B} are coupled to the base die 301_{A} using an HB process. In an embodiment, the base die 301_{A} may comprise a back-end-of-line (BEOL) stack 302. First pads 325_{A} may be provided over the BEOL stack 302 in a dielectric layer 324_{A}. The first pads 325_{A} may be a non-uniform pad architecture. That is, the first pads 325_{A} may have multiple pitches, dimensions, etc.

In an embodiment, vias 326_{A} provide a connection to a redistribution layer 322_{A}. At the redistribution layer 322_{A}, traces 323_{A} may re-route the position of the underlying first pads 325_{A}. The traces 323_{A} may be connected to an overlying HB layer that comprises the HB pads 315_{A} in a dielectric layer 312_{A} by vias 327_{A}. The HB pads 315_{A} may have a uniform pitch and dimension, similar to the HB layer 110 in FIG. 1B. In a particular embodiment, the HB pads 315_{A} may have a pitch that is approximately 40 μm or smaller, or approximately 10 μm or smaller.

The chiplets 301_{B} have a similar architecture. First pads 325_{B} are in a dielectric layer 324_{B}. The vias 326_{B} connect the first pads 325_{B} to the traces 323_{B} in the redistribution layer 322_{B}. Vias 327_{B} may then couple the traces 323_{B} to the HB pads 315_{B} in the dielectric layer 312_{B}. The dielectric layers 312_{A} and 312_{B} bond together, and the HB pads 315_{A} and 315_{B} are aligned with each other so that they bond together.

While each of the chiplets 301_{B} in FIG. 3A are shown as being substantially similar to each other, it is to be appreciated that embodiments allow for improved flexibility in using chiplets that have different pad designs. Particularly, the addition of the routing layer 322 allows for substantially any incoming pad architecture to be re-routed to conform to the uniform HB pad layout. In some embodiments, the chiplets 301_{B} and/or the base die 301_{A} may be sourced from external suppliers, and the redistribution layers 322 and uniform HB layers are formed over the existing pads by the party assembling the dies. In other embodiments, the supplier of the chiplets 301_{B} and/or the base die 301_{A} may have already incorporated the uniform HB layers into the product before sale.

In FIG. 3A, the base die 301_{A} and the chips 301_{B} both have the uniform HB layers. However, it is to be appreciated that the uniform HB layer may only be on one side of the interface in some embodiments. An example of such an embodiment is shown in FIG. 3B. Similar to the embodiment in FIG. 3A, the multi-die module 300 includes a base die 301_{A} with a BEOL stack 302_{A}. A redistribution layer 322 re-routs the first pads 325_{A} to the uniform HB layer with HB pads 315 in the dielectric layer 312. However, the chiplets 301_{B} may comprise a BEOL stack 302_{B} with non-uniform pads 325_{B}. The non-uniform pads 325_{B} may then be bonded to the HB pads 315 using hybrid bonding processes. That is, a uniform field of HB pads 315 can still be bonded to disparate pad fields of the chiplets 301_{B}. However, it is to be appreciated that such an HB process would be more challenging and adds complexity to the design of the HB pad redistribution layer 322 and may restricts geometry choice.

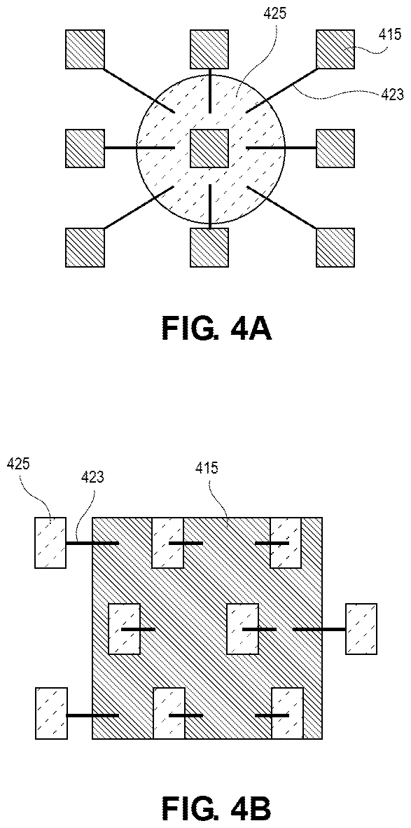

Referring now to FIGS. 4A and 4B, a zoomed in illustration of different interconnect routing schemes that may be used in accordance with embodiments disclosed herein are shown. As shown in FIG. 4A, a single first pad 425 is shown. The single first pad 425 may be a relatively larger pad than other first pads 425 on a given die. For example, the illustrated first pad 425 may be a power or ground pad. Due to the increased current that may be supplied through the first pad 425, it may be necessary to connect the first pad 425 to multiple HB pads 415. As such, a plurality of traces 423 in a redistribution layer laterally spread the first pad 425 out to the HB pads 415. While a 1:9 ratio (first pad:HB pad) is shown in FIG. 4A, it is to be appreciated that any ratio may be used in accordance with embodiments disclosed herein.

It is also possible to reverse the ratio, as shown in FIG. 4B. For example, a plurality of first pads 425 may be coupled to a single HB pad 415. In such an embodiment, the traces 423 in the redistribution layer laterally contract the first pads 425 to the single HB pad 415. Such an embodiment may be useful when the first pads 425 are part of the BEOL stack where feature sizes are typically smaller. While a 9:1 ratio is shown in FIG. 4B, it is to be appreciated that any ratio may be used in accordance with embodiments disclosed herein.

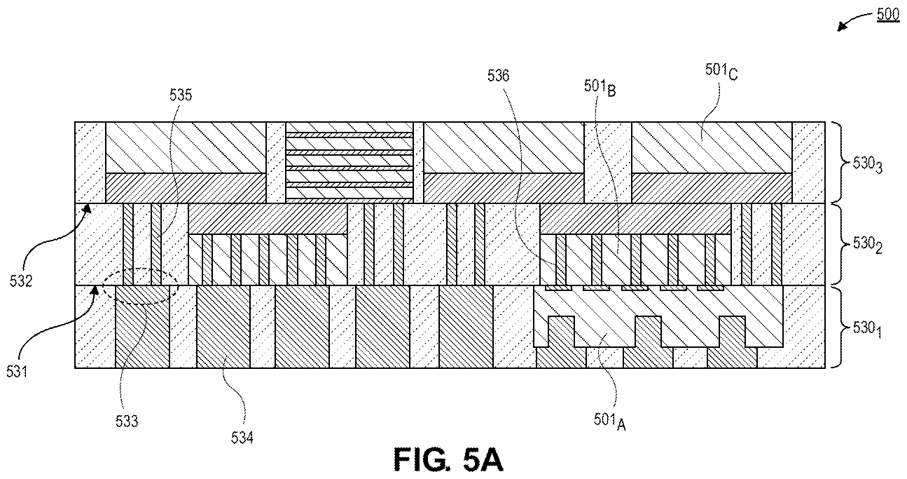

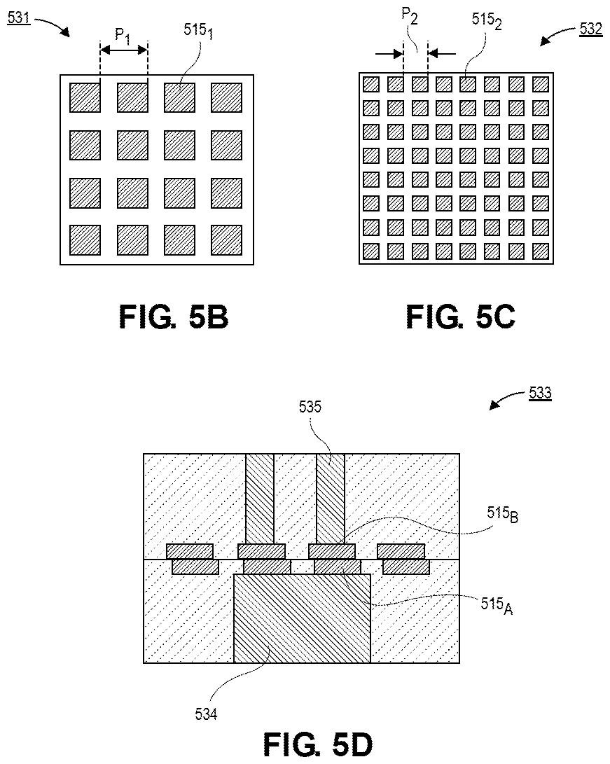

In the previously described embodiments, the multi-die modules were illustrated as having a first strata and a second strata. However, it is to be appreciated that embodiments may utilize HB layers to couple together any number of strata. An example of an embodiment with three strata 530₁-530₃ is shown in FIG. 5A.

Referring now to FIG. 5A, a cross-sectional illustration of a multi-die module 500 is shown, in accordance with an embodiment. As shown, the multi-die module 500 comprises three strata 530₁, 530₂, and 530₃. Each of the strata 530 may comprise one or more dies 501. For example, a single die 501_{A} is in the first strata 530₁, a pair of dies 501_{B} are in the second strata 530₂, and a plurality of dies 501_{C} are in the third strata 530₃. In some embodiments, the dies 501 may comprise through substrate vias (TSVs) 536 to provide electrical connections through a thickness of the dies 501. Through strata vias 534 or 535 may also be provided through the thickness of a strata 530 to provide electrical connections between strata 530.

In an embodiment, the interfaces (e.g., interface 531 and interface 532) between the strata 530 may comprise uniform HB layers. In some embodiments, both strata 530 at a given interface (e.g., strata 530₁ and strata 530₂ at interface 531) may have uniform HB layers, similar to the embodiment shown in FIG. 3A. In other embodiments, one of the strata 530 at a given interface may have a uniform HB layer, similar to the embodiment shown in FIG. 3B. In some embodiments, the interface 531 may have the same HB layer layout as the interface 532. That is, interface 531 may have HB pads with a first pitch, and interface 532 may have HB pads with the first pitch.

In other embodiments, the interface 531 may have a different HB layout than the interface 532. An example of such an embodiment is shown in FIGS. 5B and 5C. As shown in FIGS. 5A and 5B, uniform arrays of HB pads 515 are provided. However, the HB pads 515₁ at interface 531 (FIG. 5B) have a dimension and first pitch P₁ that is greater than a dimension and second pitch P₂ of the HB pads 515₂ at interface 532 (FIG. 5C).

Referring now to FIG. 5D, a zoomed in illustration of the region 533 in FIG. 5A is shown, in accordance with an embodiment. Particularly, FIG. 5D illustrates that the uniform HB pads 515_{A} and 515_{B} may also be used to provide connections to interconnects that are outside of dies. For example, through strata via 534 in strata 530₁ is coupled to a pair of through strata vias 535 in strata 530₂ by HB pads 515_{A} and 515_{B}. Also illustrated in FIG. 5D is that the HB pads 515_{A} and 515_{B} may be misaligned in some instances. Misalignment between the HB pads 515 may be the result of placement errors during assembly. That is, placing components in high volume manufacturing environments typically has some degree of inaccuracy. So long as the inaccuracy is within an acceptable margin of error, the misalignment between the HB pads 515 may be tolerated.

However, as the pitch and dimension of the HB pads continue to scale, the acceptable margin of error may be smaller than the accuracy of the pick-and-place tool. In such embodiments, adaptive patterning may be used in order to account for the inaccuracy in the placement of components. The adaptive patterning may be implemented on the traces within the redistribution layer. For example, the traces may be increased in length, decreased in length, and/or rotated in order to accommodate the inaccuracies in the placement of the component.

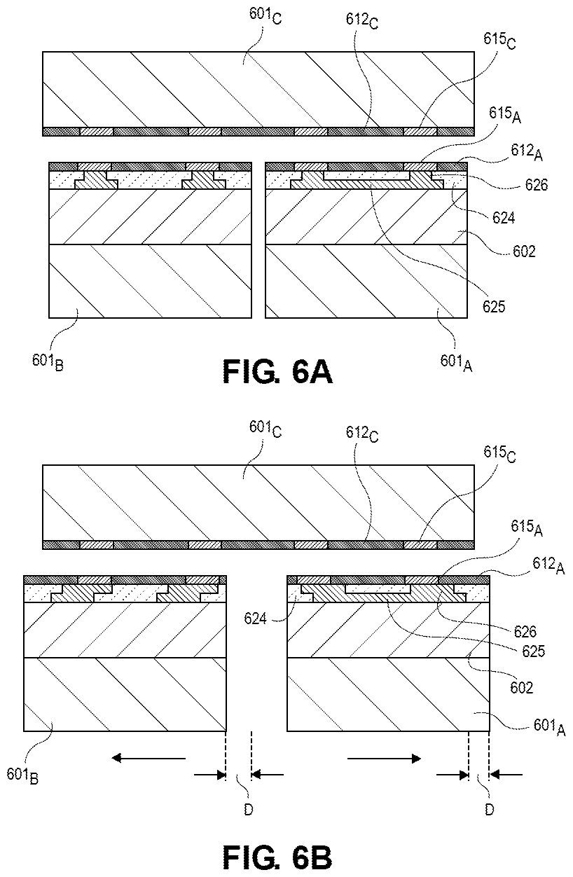

Referring now to FIG. 6A, a cross-sectional illustration of the dies 601_{A} and 601_{B} that are to be connected to die 601_{C} is shown, in accordance with an embodiment. In the embodiment in FIG. 6A, the alignment is shown as being the ideal case with zero misalignment. As shown, the pads 625 over the BEOL stack 602 are perfectly aligned with the HB pads 615_{A} in dielectric 612_{A}. As such the trace 626 in redistribution layer 624 just needs to be a via in order to make a connection between the HB pads 615_{A} and the pads 625. The HB pads 615_{C} and dielectric 612_{C} can then be brought into contact with the HB pads 615_{A} and 612_{A} (and to the HB pads and dielectric on the die 601_{B}) to make the connection between the dies 601.

However, when there is misalignment in the placement of the dies 601_{A} and 601_{B}, the traces 626 in the redistribution layer 624 can be extended to account for the misalignment. This is particularly useful in the case of two base dies 601 that are misaligned in different directions and/or magnitudes. For example, in FIG. 6B, the die 601_{A} is offset to the right a distance D, and the die 601_{B} is offset to the left a distance D. The different directions of the misalignment means that the top die 601_{C} cannot be shifted to account for the misalignment in both underlying dies 601_{A} and 601_{B}. This becomes even more problematic as the number of dies in the multi-die module increase. In order to account for the misalignment of both dies 601_{A} and 601_{B}, the traces 626 on the die 601_{A} extend to the left, and the traces 626 on the die 601_{B} extend to the right. The HB pads 615_{A} may be above the traces 626 and properly aligned with the HB pads 615_{C} on the top die 601_{C}.

It is to be appreciated that such routing can be done on-the-fly as information about the die placement is obtained. For example, the dies 601_{A} and 601_{B} may be placed in position by a pick-and-place tool. The placement of the dies 601_{A} and 601_{B} may be sensed (e.g., through imaging) to detect an offset of each die 601. The offset of each die 601 may be analyzed by software to determine the proper routing of the traces 626 to account for the misalignment. An adaptive patterning tool (e.g., direct write lithography) may be used to pattern the redistribution layers of the bottom dies 601_{A} and 601_{B}. Those skilled in the art will recognize that the use of adaptive patterning may be inferred by the analysis of several systems. Comparing the redistribution layers will show that one or more of the redistribution lines are variable between the different systems. That is, a given redistribution line compared between systems may have a non-uniform length and/or rotation.

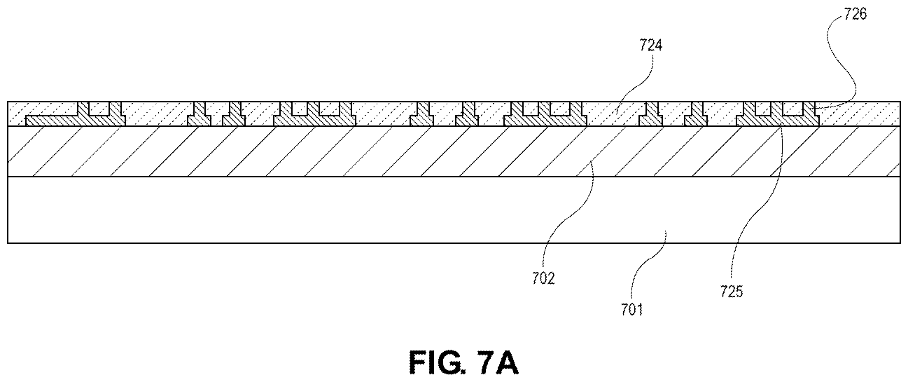

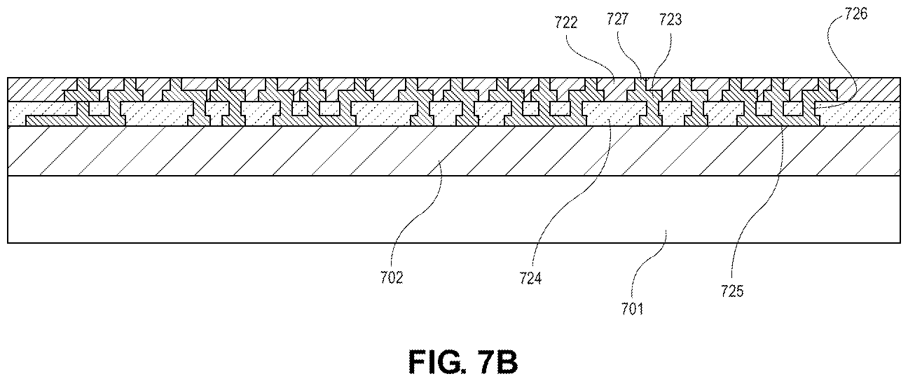

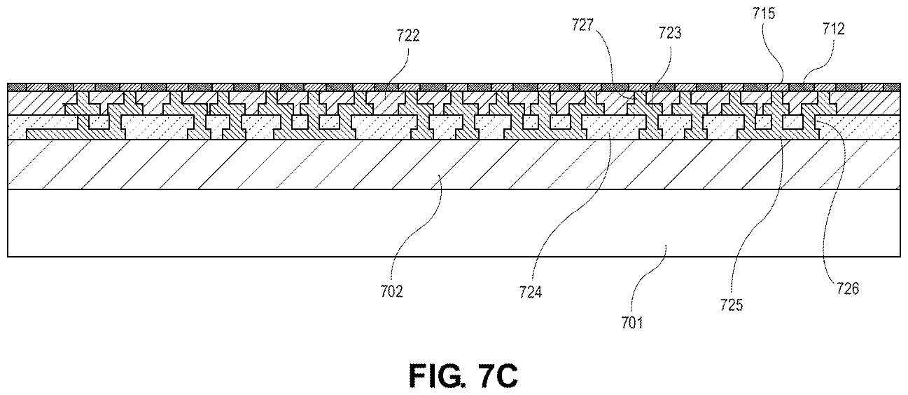

Referring now to FIGS. 7A-7C, a series of cross-sectional illustrations depicting a process for forming a die with a uniform HB layer is shown, in accordance with an embodiment.

Referring now to FIG. 7A, a cross-sectional illustration of a die 701 is shown, in accordance with an embodiment. In an embodiment, the die 701 may comprise a semiconductor substrate, such as a silicon substrate, a group III-V semiconductor substrate, or any other semiconductor substrate. Transistor devices and the like may be fabricated on the die 701. In an embodiment, a BEOL stack 702 may provide routing between transistors (not shown) and first pads 725. In an embodiment, vias 726 may extend up from the first pads 725 through a dielectric layer 724.

Referring now to FIG. 7B, a cross-sectional illustration of the die 701 after a redistribution layer 722 is patterned over the dielectric layer 724 is shown, in accordance with an embodiment. In an embodiment, the redistribution layer 722 may include traces 723 that laterally re-route the underlying first pads 725. Vias 727 extend up vertically from the traces 723 to the top of the redistribution layer 722. In an embodiment, the traces 723 and the vias 727 may be fabricated with typical fabrication processes, such as dual damascene (DD) processes, single damascene (SD) processes, or semi-additive processes (SAP)).

Referring now to FIG. 7C, a cross-sectional illustration of the die 701 after a uniform HB layer is formed over the redistribution layer 722 is shown, in accordance with an embodiment. In an embodiment, the HB layer comprises a dielectric layer 712 and a plurality of HB pads 715. The HB pads 715 may have a uniform pitch across the die 701. For example, the pitch may be approximately 40 μm or smaller or approximately 10 μm or smaller. Additionally, the HB pads 715 may have a uniform dimension. The HB pads 715 may be fabricated using typical processes, such as DD, SD, or SAP.

In an embodiment, the HB pads 715 and the dielectric layer 712 may then be planarized with a CMP process. Due to the uniform metal density and uniformly sized HB pads 715, the CMP process may be less complex than a process that needs to be used for existing HB layers, such as the one shown in FIG. 1A. In an embodiment, a top surface of the HB pads 715 may be substantially coplanar with a top surface of the dielectric layer 712. In other embodiments, a top surface of the HB pads 715 may be recessed below the top surface of the dielectric layer 712 between approximately 0 nm and approximately 5 nm.

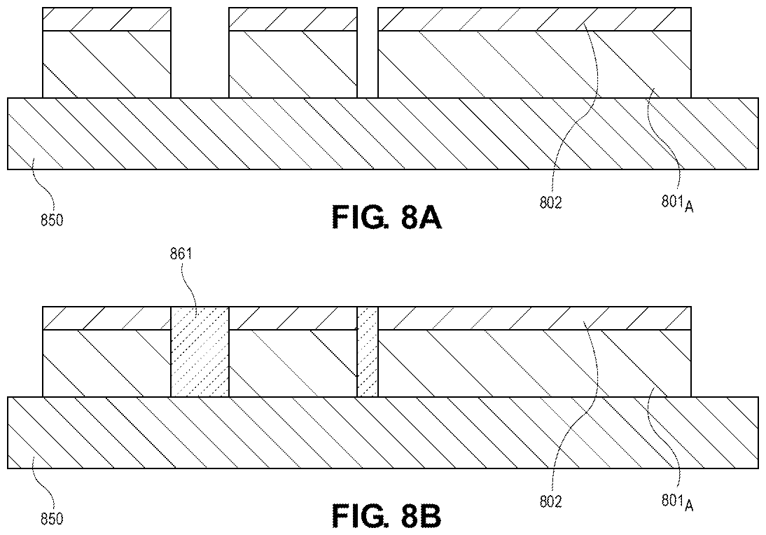

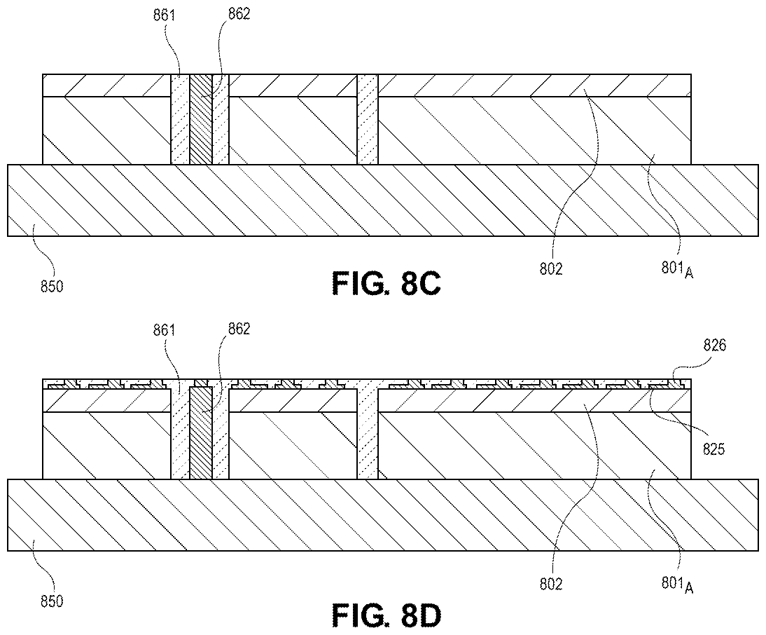

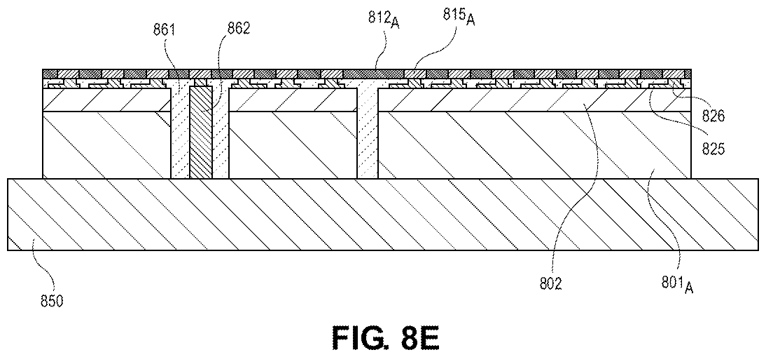

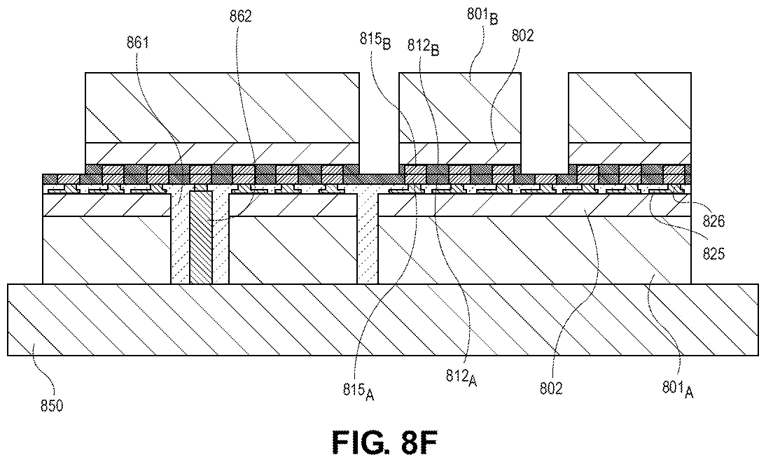

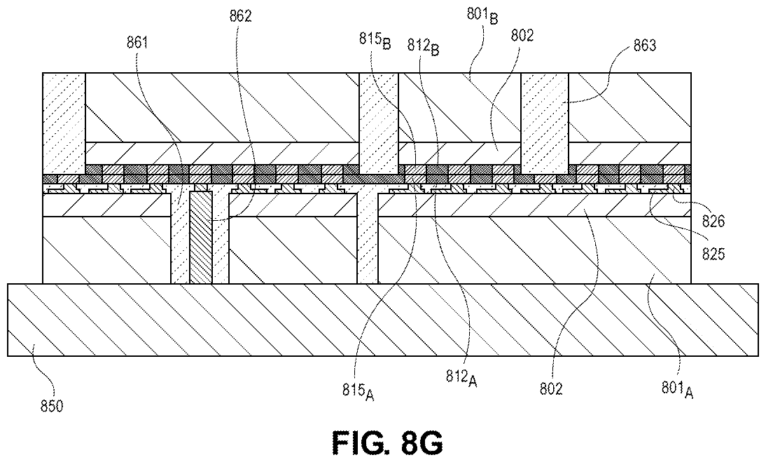

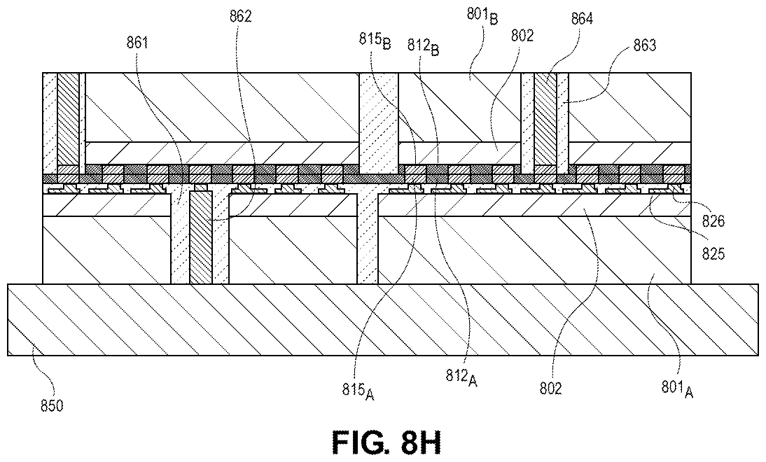

Referring now to FIGS. 8A-8H, a series of cross-sectional illustrations depicting a process for forming a multi-die module with HB layers is shown, in accordance with an embodiment. In the embodiment shown, adaptively patterned redistribution layers are used to account for misalignment in the placement of bottom dies.

Referring now to FIG. 8A, a cross-sectional illustration of dies 801 placed on a carrier substrate 850 is shown, in accordance with an embodiment. Carrier substrate 850 may also be replaced with an underlying strata of dies and/or components when the dies 801 are not the bottom strata of a multi-die module. While die 801_{A} is specifically referenced, it is to be appreciated that the other bottom dies may have similar structures and features. In an embodiment, the die 801 may comprise a BEOL stack 802 to connect to transistor devices (not shown).

After the placement of the dies 801 on the carrier substrate 850, the true position of the dies 801 may be determined. For example, the true position may be determined by imaging or the like. The true position of the dies 801 may provide an offset value and/or a rotational offset value for each of the dies 801. The offset values may be used in subsequent operations to provide adaptive patterning to accommodate the offset.

Referring now to FIG. 8B, a cross-sectional illustration of the dies 801 after a dielectric layer 861 is disposed over and around the dies 801 is shown, in accordance with an embodiment. In an embodiment, the dielectric layer 861 may be planarized so that a top surface of the BEOL stack 802 is exposed.

Referring now to FIG. 8C, a cross-sectional illustration of the dies 801 after a through strata via 862 is formed is shown, in accordance with an embodiment. In an embodiment, the measured offsets of the dies 801 may be used to properly position the through strata via 862. In other embodiments, the through strata via 862 may be omitted.

Referring now to FIG. 8D, a cross-sectional illustration of the dies 801 after a redistribution layer is formed over the BEOL stack 802 is shown, in accordance with an embodiment. The redistribution layer may comprise pads 825 and vias 826. The offset values determined above may be used to modify the vias 826. For example, the vias may be extended laterally into traces to account for inaccuracies in the placement of the dies 801. In an embodiment, one or both of the pads 825 and the vias 826 may be fabricated using an adaptive patterning process, such as direct write lithography, in conjunction with DD, SD, or SAP. In other embodiments, one or both of the pads 825 and the vias 826 may be fabricated with DD, SD, or SAP without the use of adaptive patterning.

Referring now to FIG. 8E, a cross-sectional illustration of the dies 801 after a uniform HB layer is disposed over the vias 826 is shown, in accordance with an embodiment. The HB layer may comprise a dielectric layer 812_{A} and a plurality of HB pads 815_{A}. In an embodiment, the HB pads 815_{A} may have a uniform pitch. For example, the pitch may be approximately 40 μm or less or approximately 10 μm or less. In an embodiment, the HB pads 815_{A} may also have a uniform dimension.

Referring now to FIG. 8F, a cross-sectional illustration of the dies 801 after top dies 801_{B} are attached to the bottom dies 801_{A} is shown, in accordance with an embodiment. Each of the top dies 801_{B} may comprise a BEOL stack 802, and an HB layer with a dielectric 812_{B} and a plurality of HB pads 815_{B}. In an embodiment, the HB pads 815_{B} may be aligned with the underlying HB pads 815_{A} on the bottom dies 801_{A}. In an embodiment, an HB process may be used to secure the dielectric 812_{A} to the dielectric 812_{B} and the HB pads 815_{A} to the HB pads 815_{B}.

Referring now to FIG. 8G, a cross-sectional illustration of the multi-die module after a dielectric layer 863 is disposed over and between the top dies 801_{B} is shown, in accordance with an embodiment. In an embodiment, the dielectric layer 863 is planarized with a backside surface of the top dies 801_{B}.

Referring now to FIG. 8H, a cross-sectional illustration of the multi-die module after through strata vias 864 are formed is shown, in accordance with an embodiment. In an embodiment, the through strata vias 864 may land on HB pads 815_{B} in some embodiments. In other embodiments, the through strata vias 864 may be omitted. For example, if the second dies 801 are the top strata, then additional through strata vias 864 may not be necessary.

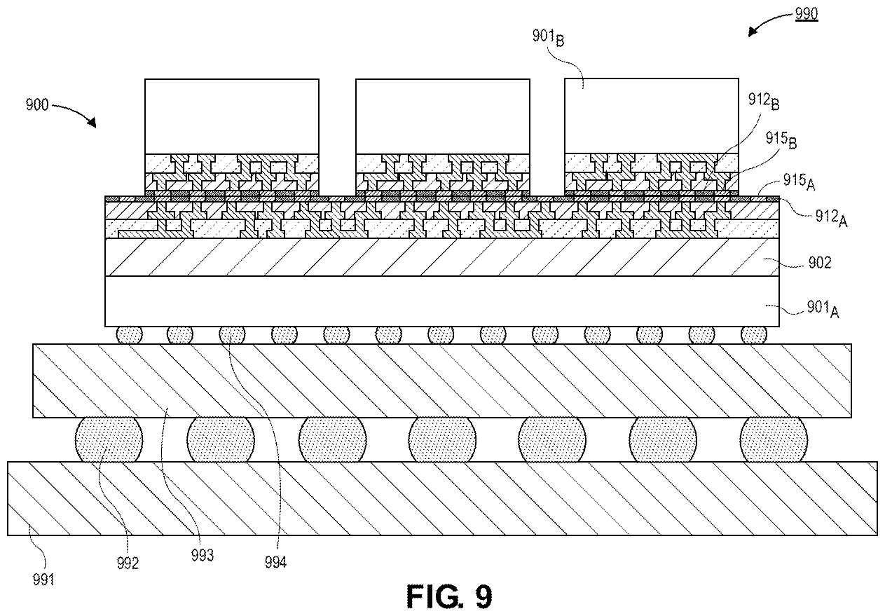

Referring now to FIG. 9, a cross-sectional illustration of an electronic system 990 is shown, in accordance with an embodiment. In an embodiment, the electronic system 990 comprises a board 991, such as a printed circuit board (PCB). In an embodiment, the board 991 may be coupled to a package substrate 993 by interconnects 992. The interconnects 992 may comprise solder balls, sockets, or the like. In an embodiment, a multi-die module 900 is coupled to the package substrate 993 by interconnects 994.

In an embodiment, the multi-die module 900 may be substantially similar to any of the multi-die modules described in greater detail herein. In a particular embodiment, the multi-die module 900 comprises a base die 901_{A}. A BEOL stack 902 may be over the base die 901_{A}. In an embodiment a uniform HB layer comprising a dielectric 912_{A} and a plurality of HB pads 915_{A} is provided over the base die 901_{A}. The HB pads 915_{A} may have a uniform pitch and dimension.

In an embodiment, the multi-die module 900 may further comprise a plurality of top dies 901_{B}. The top dies 901_{B} may be coupled to the base die 901_{A} by a second HB layer. The second HB layer may comprise a dielectric layer 912_{B} and a plurality of HB pads 915_{B}. The HB pads 915_{B} may have a uniform pitch and dimension that is substantially equal to the pitch and dimension of the HB pads 915_{A}. In an embodiment, the dielectric 912_{A} is bonded to the dielectric 912_{B}, and the HB pads 915_{A} are bonded to the HB pads 915_{B} (e.g., through interdiffusion). In some embodiments, there may not be a discernable seam between the HB pads 915_{A} and the HB pads 915_{B}.

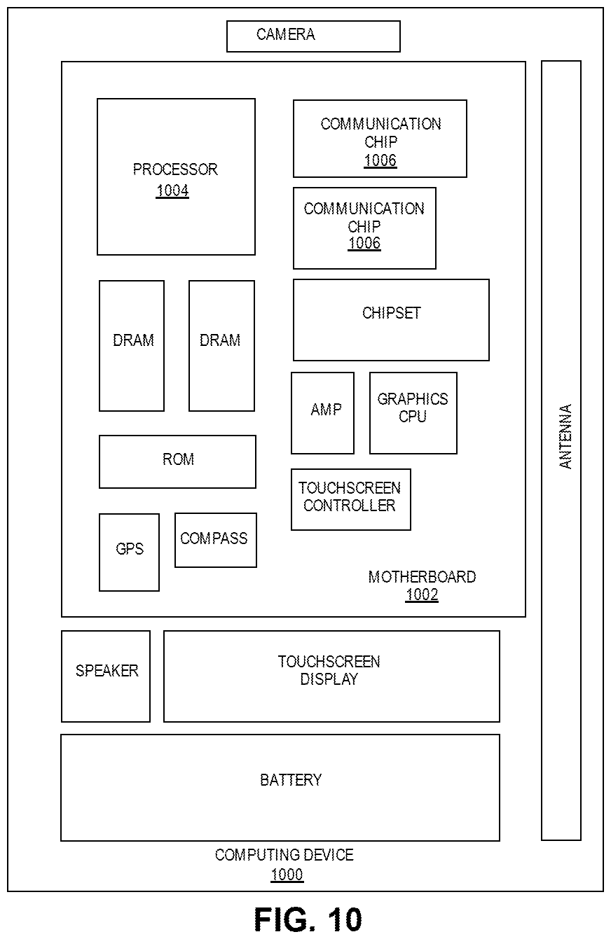

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor may be part of an electronic package that comprises a multi-die module, wherein different strata of the multi-die module are coupled together with uniform HB layers, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip may be part of an electronic package that comprises a multi-die module, wherein different strata of the multi-die module are coupled together with uniform HB layers, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a semiconductor die, comprising: a die substrate; a pad layer over the die substrate, wherein the pad layer comprises first pads with a first dimension and a first pitch and second pads with a second dimension and a second pitch; and a hybrid bonding layer over the pad layer, wherein the hybrid bonding layer comprises: a dielectric layer; and an array of hybrid bonding pads in the dielectric layer, wherein the hybrid bonding pads comprise a third dimension and a third pitch.

Example 2: the semiconductor die of Example 1, wherein the entire array of hybrid bonding pads have the third dimension and the third pitch.

Example 3: the semiconductor die of Example 1 or Example 2, wherein individual ones of the first pads are coupled to a corresponding one of the hybrid bonding pads.

Example 4: the semiconductor die of Example 3, wherein the first pads are input/output (I/O) pads.

Example 5: the semiconductor die of Examples 1-4, wherein individual ones of the second pads are coupled to a plurality of the hybrid bonding pads.

Example 6: the semiconductor die of Example 5, wherein the second pads are power or ground pads.

Example 7: the semiconductor die of Examples 1-6, wherein the third pitch is approximately 40 μm or smaller.

Example 8: the semiconductor die of Example 7, wherein the third pitch is approximately 10 μm or smaller.

Example 9: the semiconductor die of Examples 1-8, wherein first surfaces of the hybrid bonding pads are substantially coplanar with a first surface of the dielectric layer.

Example 10: an electronic package comprising: a first die, wherein the first die comprises: a first die substrate; and a first hybrid bonding layer over the first die substrate, wherein the first hybrid bonding layer comprises: a first dielectric layer; and an array of first hybrid bonding pads in the first dielectric layer, wherein the first hybrid bonding pads have a first pitch; and a second die coupled to the first die, wherein the second die comprises: a second die substrate; and a second hybrid bonding layer over the second die substrate, wherein the second hybrid bonding layer comprises: a second dielectric layer; and an array of second hybrid bonding pads in the second dielectric layer, wherein the second hybrid bonding pads have the first pitch, and wherein the second hybrid bonding pads are directly connected to the first hybrid bonding pads.

Example 11: the electronic package of Example 10, wherein there is no seam between the first hybrid bonding pads and the second hybrid bonding pads.

Example 12: the electronic package of Example 10 or Example 11, wherein the second dielectric layer is bonded to the first dielectric layer.

Example 13: the electronic package of Examples 10-12, wherein the array of first hybrid bonding pads is larger than the array of second hybrid bonding pads.

Example 14: the electronic package of Example 13, further comprising: a third die coupled to the first die, wherein the third die comprises: a third die substrate; and a third hybrid bonding layer over the third die substrate, wherein the third hybrid bonding layer comprises: a third dielectric layer; and an array of third hybrid bonding pads in the third dielectric layer, wherein the third hybrid bonding pads have the first pitch, and wherein the third hybrid bonding pads are directly connected to the first hybrid bonding pads.

Example 15: the electronic package of Examples 10-14, wherein the second die further comprises: a pad layer between the second die substrate and the second hybrid bonding layer, wherein the pad layer comprises first pads with a second pitch that is different than the first pitch; and a redistribution layer between the pad layer and the second hybrid bonding layer, wherein the redistribution layer couples individual ones of the first pads to corresponding ones of the second hybrid bonding pads.

Example 16: the electronic package of Example 15, further comprising: second pads in the pad layer, wherein the second pads have a third pitch that is different from the first pitch and the second pitch, and wherein the redistribution layer couples individual ones of the second pads to a plurality of the hybrid bonding pads.

Example 17: the electronic package of Example 16, wherein the first pads are input/output (I/O) pads and wherein the second pads are power and/or ground pads.

Example 18: the electronic package of Examples 15-17, wherein the redistribution layer is fabricated with an adaptive patterning process to account for misalignment between the first die and the second die.

Example 19: the electronic package of Examples 10-18, wherein one or more of the first hybrid bonding pads are dummy pads that are not coupled to active circuitry.

Example 20: the electronic package of Examples 10-19, wherein the first pitch is approximately 40 μm or smaller.

Example 21: the electronic package of Example 20, wherein the first pitch is approximately 10 μm or smaller.

Example 22: an electronic system, comprising: a first strata, wherein the first strata comprises: a first die; and a first hybrid bonding layer with first pads with a first pitch; a second strata over the first strata, wherein the second strata comprises: a second die; and a second hybrid bonding layer with second pads with the first pitch, and wherein the first strata is bonded to the second strata by an interface between the first hybrid bonding layer and the second hybrid bonding layer.

Example 23: the electronic system of Example 22, wherein the second strata further comprises: a third hybrid bonding layer with third pads with a second pitch, and wherein the electronic system further comprises: a third strata over the second strata, wherein the third strata comprises: a third die; and a fourth hybrid bonding layer with fourth pads with the second pitch, wherein the second strata is bonded to the third strata by an interface between the third hybrid bonding layer and the fourth hybrid bonding layer.

Example 24: the electronic system of Example 23, wherein the second pitch is smaller than the first pitch.

Example 25: the electronic system of Examples 22-24, further comprising: a board coupled to the first strata.

What is claimed is:

1. A semiconductor die, comprising:
a die substrate;
a pad layer over the die substrate, wherein the pad layer comprises first pads with a first dimension and a first pitch and second pads with a second dimension and a second pitch; and
a hybrid bonding layer over the pad layer, wherein the hybrid bonding layer comprises:
a dielectric layer; and
an array of hybrid bonding pads in the dielectric layer, wherein the hybrid bonding pads comprise a third dimension and a third pitch.

2. The semiconductor die of claim 1, wherein the entire array of hybrid bonding pads have the third dimension and the third pitch.

3. The semiconductor die of claim 1, wherein individual ones of the first pads are coupled to a corresponding one of the hybrid bonding pads.

4. The semiconductor die of claim 3, wherein the first pads are input/output (I/O) pads.

5. The semiconductor die of claim 1, wherein individual ones of the second pads are coupled to a plurality of the hybrid bonding pads.

6. The semiconductor die of claim 5, wherein the second pads are power or ground pads.

7. The semiconductor die of claim 1, wherein the third pitch is approximately 40 μm or smaller.

8. The semiconductor die of claim 7, wherein the third pitch is approximately 10 μm or smaller.

9. The semiconductor die of claim 1, wherein first surfaces of the hybrid bonding pads are substantially coplanar with a first surface of the dielectric layer.

10. An electronic package comprising:
a first die, wherein the first die comprises:
a first die substrate; and
a first hybrid bonding layer over the first die substrate, wherein the first hybrid bonding layer comprises:
a first dielectric layer; and
an array of first hybrid bonding pads in the first dielectric layer, wherein the first hybrid bonding pads have a first pitch; and
a second die coupled to the first die, wherein the second die comprises:
a second die substrate; and
a second hybrid bonding layer over the second die substrate, wherein the second hybrid bonding layer comprises:
a second dielectric layer; and
an array of second hybrid bonding pads in the second dielectric layer, wherein the second hybrid bonding pads have the first pitch, and wherein the second hybrid bonding pads are directly connected to the first hybrid bonding pads.

11. The electronic package of claim 10, wherein there is no seam between the first hybrid bonding pads and the second hybrid bonding pads.

12. The electronic package of claim 10, wherein the second dielectric layer is bonded to the first dielectric layer.

13. The electronic package of claim 10, wherein the array of first hybrid bonding pads is larger than the array of second hybrid bonding pads.

14. The electronic package of claim 13, further comprising:
a third die coupled to the first die, wherein the third die comprises:
a third die substrate; and
a third hybrid bonding layer over the third die substrate, wherein the third hybrid bonding layer comprises:
a third dielectric layer; and
an array of third hybrid bonding pads in the third dielectric layer, wherein the third hybrid bonding pads have the first pitch, and wherein the third hybrid bonding pads are directly connected to the first hybrid bonding pads.

15. The electronic package of claim 10, wherein the second die further comprises:
a pad layer between the second die substrate and the second hybrid bonding layer, wherein the pad layer comprises first pads with a second pitch that is different than the first pitch; and
a redistribution layer between the pad layer and the second hybrid bonding layer, wherein the redistribution layer couples individual ones of the first pads to corresponding ones of the second hybrid bonding pads.

16. The electronic package of claim 15, further comprising:
second pads in the pad layer, wherein the second pads have a third pitch that is different from the first pitch and the second pitch, and wherein the redistribution layer couples individual ones of the second pads to a plurality of the hybrid bonding pads.

17. The electronic package of claim 16, wherein the first pads are input/output (I/O) pads and wherein the second pads are power and/or ground pads.

18. The electronic package of claim 15, wherein the redistribution layer is fabricated with an adaptive patterning process to account for misalignment between the first die and the second die.

19. The electronic package of claim 10, wherein one or more of the first hybrid bonding pads are dummy pads that are not coupled to active circuitry.

20. The electronic package of claim 10, wherein the first pitch is approximately 40 μm or smaller.

21. The electronic package of claim 20, wherein the first pitch is approximately 10 μm or smaller.

22. An electronic system, comprising:
a first strata, wherein the first strata comprises:
a first die; and
a first hybrid bonding layer with first pads with a first pitch;
a second strata over the first strata, wherein the second strata comprises:
a second die; and
a second hybrid bonding layer with second pads with the first pitch, and wherein the first strata is bonded to the second strata by an interface between the first hybrid bonding layer and the second hybrid bonding layer.

23. The electronic system of claim 22, wherein the second strata further comprises:
a third hybrid bonding layer with third pads with a second pitch, and wherein the electronic system further comprises:
a third strata over the second strata, wherein the third strata comprises:
a third die; and
a fourth hybrid bonding layer with fourth pads with the second pitch, wherein the second strata is bonded to the third strata by an interface between the third hybrid bonding layer and the fourth hybrid bonding layer.

24. The electronic system of claim 23, wherein the second pitch is smaller than the first pitch.

25. The electronic system of claim 22, further comprising:
a board coupled to the first strata.
